(19) United States
(12) Patent Application Publication
(10) Pub. No.: US 2003/0153175 A1
(43) Pub. Date: Aug. 14, 2003

(54) METHOD OF PREVENTING ALUMINUM SPUTTERING DURING OXIDE VIA ETCHING

(76) Inventors: GUY BLALOCK, BOISE, ID (US); DAVID S. BECKER, BOISE, ID (US)

Correspondence Address: JOSEPH A WALKOWSKI, TRASK BRITT AND ROSSA, P O BOX 2550, SALT LAKE CITY, UT, 841102550

(21) Appl. No.: 08/892,560

(22) Filed: Jul. 14, 1997

Related U.S. Application Data
(63) Continuation of application No. 08/657,056, filed on May 24, 1996, now abandoned.
Application No. 08/657,056 is a continuation of application No. 08/375,218, filed on Jan. 19, 1995, now abandoned.

(51) Int. Cl. H01L 21/4763

(52) U.S. Cl. 438/637

(57) ABSTRACT

In a double metal process for forming conductive contacts to integrated circuit structures, a method for preventing the sputtering of non-conductive aluminum compounds onto via sidewalls during the anisotropic oxide etch. A layer of nitride is deposited atop aluminum buried first metal pads before deposited of the silicon dioxide layer. A selective anisotropic oxide etch which selectively stops on the nitride is used to form the via through the oxide layer. Then an isotropic low-powered dry nitride etch extends the via through the nitride to the aluminum pad without producing unwanted sputtering.

### FIELD OF THE INVENTION

This invention relates to semiconductor integrated circuit fabrication and more particularly to improving metal-to-metal contacts in double metal contact formation processes.

### BACKGROUND OF THE INVENTION

In order for integrated circuits (ICs) to communicate electrically with the outside world, electrical contact must be made to certain device elements in the integrated circuit. Typically, this involves forming conductive metal contact pads on the surface of the integrated circuit chip which reach down through an insulating dielectric layer to contact certain device elements.

One method which has been developed to create these conductive metal contacts is the so-called double metal process. In this process, a first conductive metal layer is deposited and etched to form what will become buried metal pads which are connected to device elements (or conductive structures which are, in turn, connected to device elements). The pads are then buried under an insulating layer of dielectric material such as silicon dioxide (oxide). Trenches or vias are then etched through the oxide, down to the buried first metal pads. The vias are then filled with a second conductive metal thereby forming the double metal connection.

Traditionally, aluminum has been used as both the first and second metal because of its high conductivity and the ease with which it can be deposited and etched. However, as ICs are further miniaturized and pattern densities increase, the size of the contact vias decrease to the point where aluminum, used as the second metal, no longer provides an adequate electrical contact with the first metal pad. This is largely due to aluminum's high coefficient of thermal expansion.

It has been proposed that creating a vertically side-walled via using anisotropic etching techniques and filling it with either tungsten, tungsten alloys, titanium or titanium alloys as the second metal would accommodate higher pattern densities. FIGS. 1a-1d show successive cross-sectional schematic diagrams of an in-process semiconductor IC wherein tungsten is used as the second metal (metal #2) in forming a contact through a via having vertical side-walls to a first metal (metal #1) pad of aluminum.

The double metal process begins by depositing a first layer of aluminum 1 atop the exposed surface of the chip 2 through chemical vapor deposition (CVD) or other deposition means. The first metal layer of aluminum is then etched to form first metal contact pads 3 and 4. The pads are then buried beneath a layer of insulating dielectric material 5 such as silicon dioxide (oxide). A photomask 6 is then created atop the oxide layer. The photomask is patterned with apertures 7, 8 corresponding to locations where vias will be etched through the oxide layer down to the aluminum pads.

An anisotropic etch is used to create vias 9, 10 having substantially vertical side-walls 11 through the oxide layer 5, down to the upper surface of the aluminum first metal pads 3, 4. However, when the etch reaches the surface of the aluminum pads, it does not stop immediately. During over-etch at the aluminum interface, the etch chemistry produces by-products of non-volatile, non-conductive compounds of aluminum, such as aluminum fluoride, which are back-sputtered and adhere to the via sidewalls in the form of films 12. These films are difficult to control and extremely difficult to remove from the depths of the contact vias. Once the tungsten is deposited into the via, the existence of the films severely reduces the conductivity of the tungsten/aluminum interface because the surface area of the metal #1 to metal #2 interface has been reduced.

The only way that is known to reduce the sputtering effect during an anisotropic via etching is to reduce the power during that etch. The resulting process however, is very slow and still exhibits some sputter residue. A wet etch may be used, however, it is slow and very isotropic, resulting in an unacceptable profile.

It would therefore be advantageous to have a relatively fast contact via formation process which does not create back-sputtering of non-conductive aluminum compounds.

### SUMMARY OF THE INVENTION

The principal and secondary objects of this invention are to provide, in a double metal process, a method for creating contact vias through an oxide layer to the surface of a buried aluminum first metal pad without forming non-conductive back-sputtered aluminum compounds on the via sidewalls.

These and other objects are achieved by depositing a layer of silicon nitride atop the upper surface of the first metal layer or metal regions prior to the deposition of the oxide layer. The formation of the contact vias is done using an oxide etch which selectively stops upon contact with the nitride layer. A second isotropic low-powered dry nitride etch is then performed to extend the via through the nitride layer to the surface of the aluminum first metal layer. The second isotropic low-powered dry nitride etch does not interact with the surface of the aluminum pads to form any non-conductive back.-sputtered films on the via side-walls.

Alternatively, most of the via may be formed by first using a low selective (oxide to nitride) standard etch down to a point just above the nitride layer, then performing the oxide etch which selectively stops on nitride and the isotropic low-powered dry nitride etch.

### BRIEF DESCRIPTION OF THE DRAWING

FIG. 1a is a prior art schematic cross-sectional view of an in-process semiconductor integrated circuit after the deposition of a first metal layer in a double metal contact process;

FIG. 1b is the structure of FIG. 1a after etching the metal layer to form first metal pads;

FIG. 1c is the structure of FIG. 1b after the deposition of a layer of oxide and the formation of a patterning mask atop the oxide layer;

FIG. 1d is the structure of FIG. 1c after contact vias have been anisotropically etched to the surface of the first metal pads;

FIG. 2a is an in-process schematic cross-sectional view of a semiconductor integrated circuit chip after formation of the first metal pads in a double metal process;

FIG. 2b is the structure of FIG. 2a after the deposition of a layer of silicon nitride;

FIG. 2c is the structure of FIG. 2b after deposition of an oxide layer atop the nitride layer and the formation patterning mask atop the oxide layer;

FIG. 2d is the structure of FIG. 2c after performing a high selective anisotropic etch through the oxide layer, stopping on the nitride layer;

FIG. 2e is the structure of FIG. 2d after an isotropic low-powered dry nitride etch through the nitride layer to the surface of the first metal pads;

FIG. 3a is an in-process schematic cross-sectional view of an in-process semiconductor chip using the second embodiment of the invention wherein a layer of aluminum has been deposited upon the surface of the chip and a layer of nitride has been deposited atop the aluminum layer;

FIG. 3b shows the structure of FIG. 3a after a photo-patterning etch step creates first metal pads having nitride cap regions;

FIG. 3c is the structure of FIG. 3b after deposition of an oxide layer and the formation of a patterning mask atop the oxide layer;

FIG. 3d is the structure of FIG. 3c after performing an anisotropic etch through the oxide layer, selectively stopping on the nitride cap regions; and

FIG. 30 is the structure of FIG. 3d after an isotropic low-powered dry nitride etch through the nitride caps to the surface of the first metal pads.

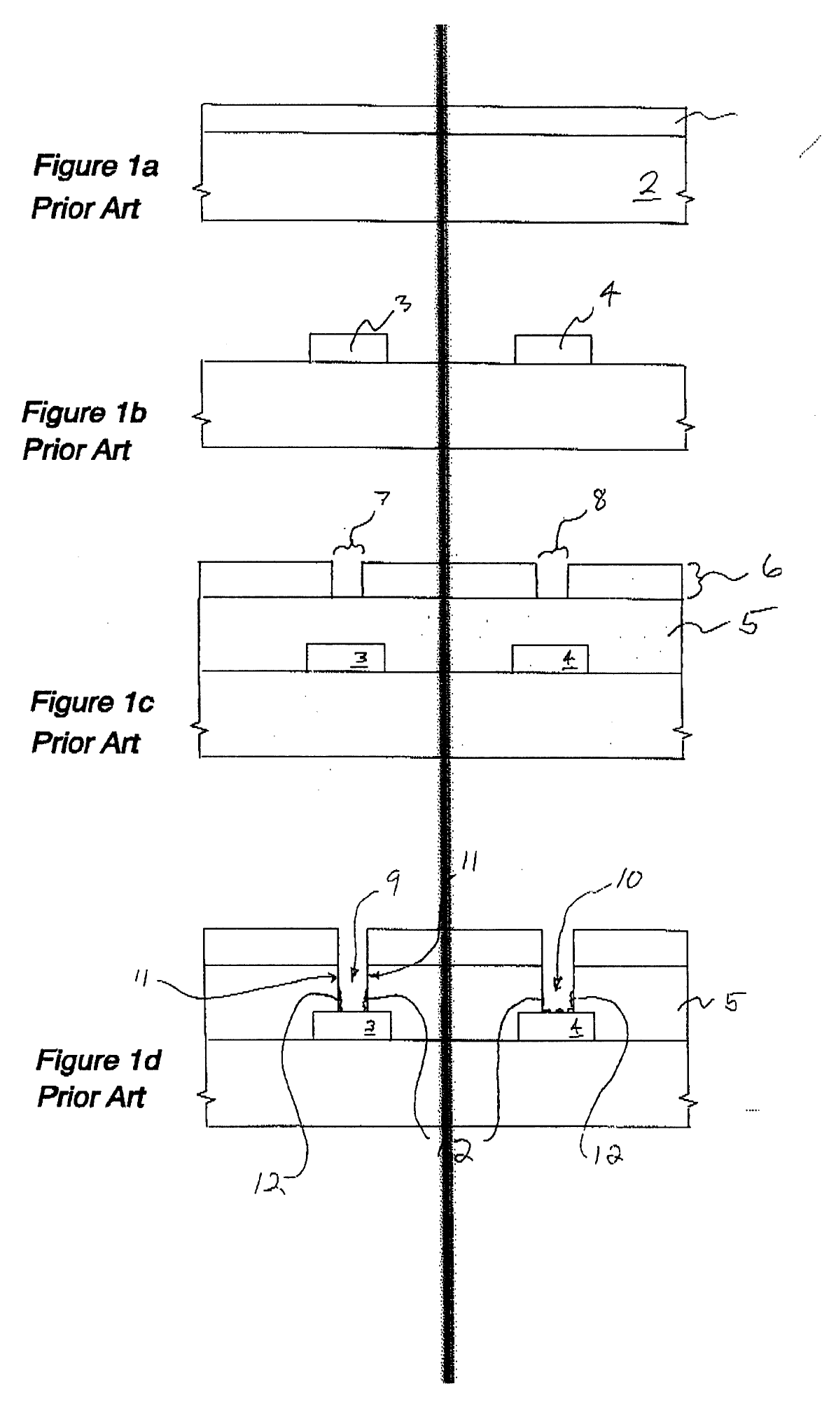

### DESCRIPTION OF THE PREFERRED EMBODIMENT OF THE INVENTION

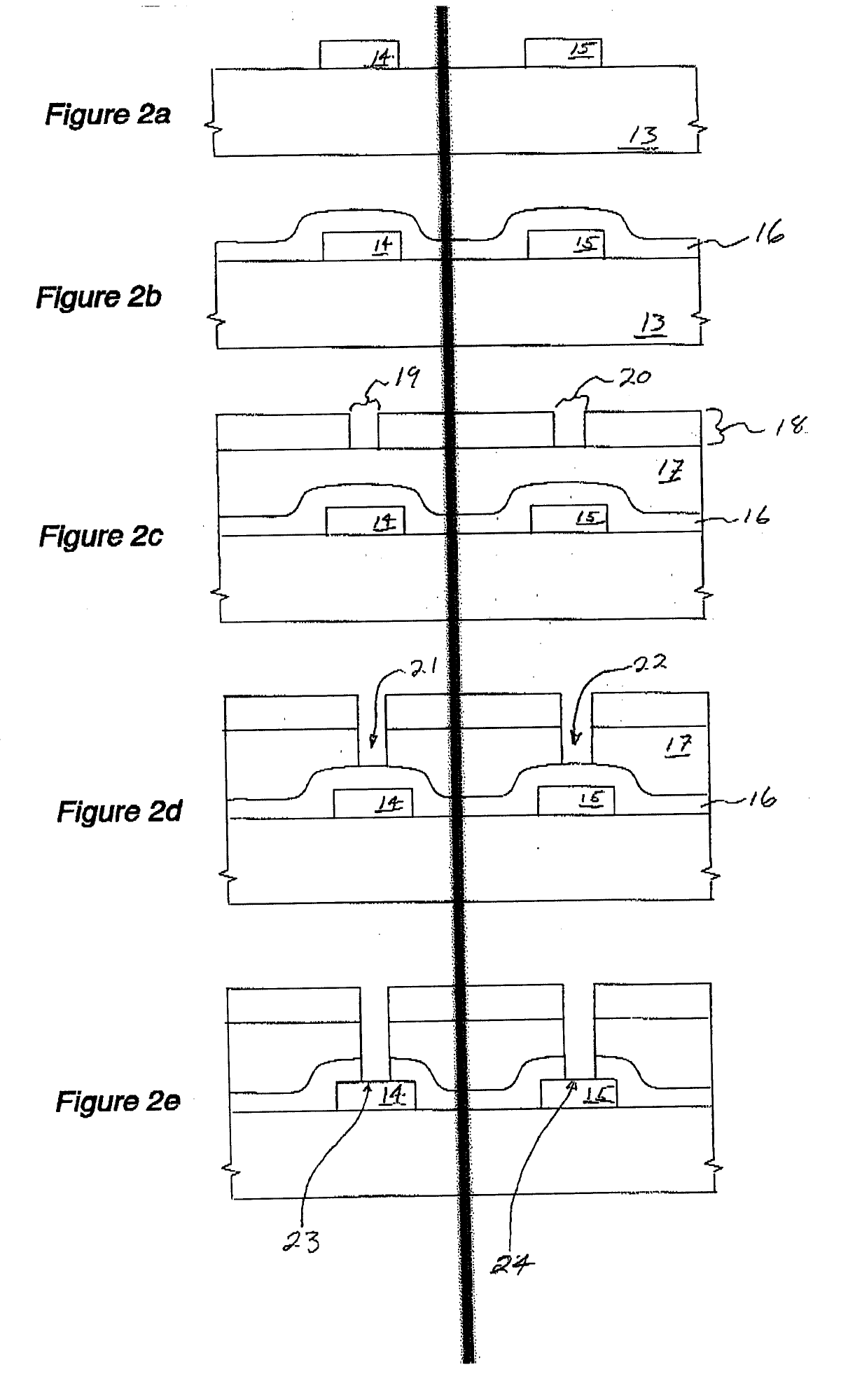

Referring now to the drawing, FIG. 2a shows a schematic cross-sectional view of a portion of an in-process semiconductor integrated circuit chip wherein the integrated circuit components have been created within a semiconductor substrate 13. A double metal contact formation process has been initiated by forming first metal pads 14, 15 atop the substrate and in contact with certain device elements or other conductive structures on or within the integrated circuit. The first metal pads are made of aluminum.

In FIG. 2b, a thin layer of silicon nitride 16 (approximately 100 to 200 angstroms thick) has been blanket deposited atop the surface of the chip to cover exposed portions of the substrate 13 and exposed surfaces of the first metal pads 14, 15.

In FIG. 2c, a layer of silicon dioxide 17 has been blanket deposited atop the nitride layer 16. A photo-resist mask 18 has been formed atop the oxide layer 17 and patterned with apertures 19, 20 corresponding to the locations where contact vias will be created.

In FIG. 2d, a first anisotropic etch through the apertures in the mask forms contact vias 21, 22 through the oxide layer 17, selectively stopping in the nitride layer 16 situated above the first metal pads 14, 15. A detailed description of this type of etch is disclosed by Blalock et al. in U.S. Pat. No. 5,286,344, Process for Selectively Etching a Layer of Silicon Dioxide on an Underlying Stop Layer of Silicon Nitride.

FIG. 2e shows that the depth of the via is extended through the nitride layer 16 to the upper surface 23, 24 of each of the first metal pads 14, 15 by performing a second isotropic low-powered dry nitride etch. Details of the nitride etch chemistry are disclosed by Keller and Gould in U.S. Pat. No. 5,338,395, Method for Enhancing Etch Uniformity Useful in Etching Submicron Nitride Features.

Since the first high powered anisotropic oxide etch does not encounter any aluminum, none of the non-conductive aluminum compounds are created or back-sputtered onto the sidewalls of the vias. The subsequent low-powered isotropic nitride etch through the nitride layer uses a chemistry far different from the anisotropic oxide etch. Its interaction with the aluminum metal does not create any of the aluminum compounds which would coat the via sidewalls thereby narrowing the sidewalls and reducing the width of the via and thereby reducing the conductivity of the resulting deposited second metal contact.

The second nitride etch may be performed with the photo-resist mask left in place or after stripping the mask.

In a second embodiment of the invention, the nitride layer is deposited atop the aluminum layer prior to etching the aluminum layer to form the first metal contact pads.

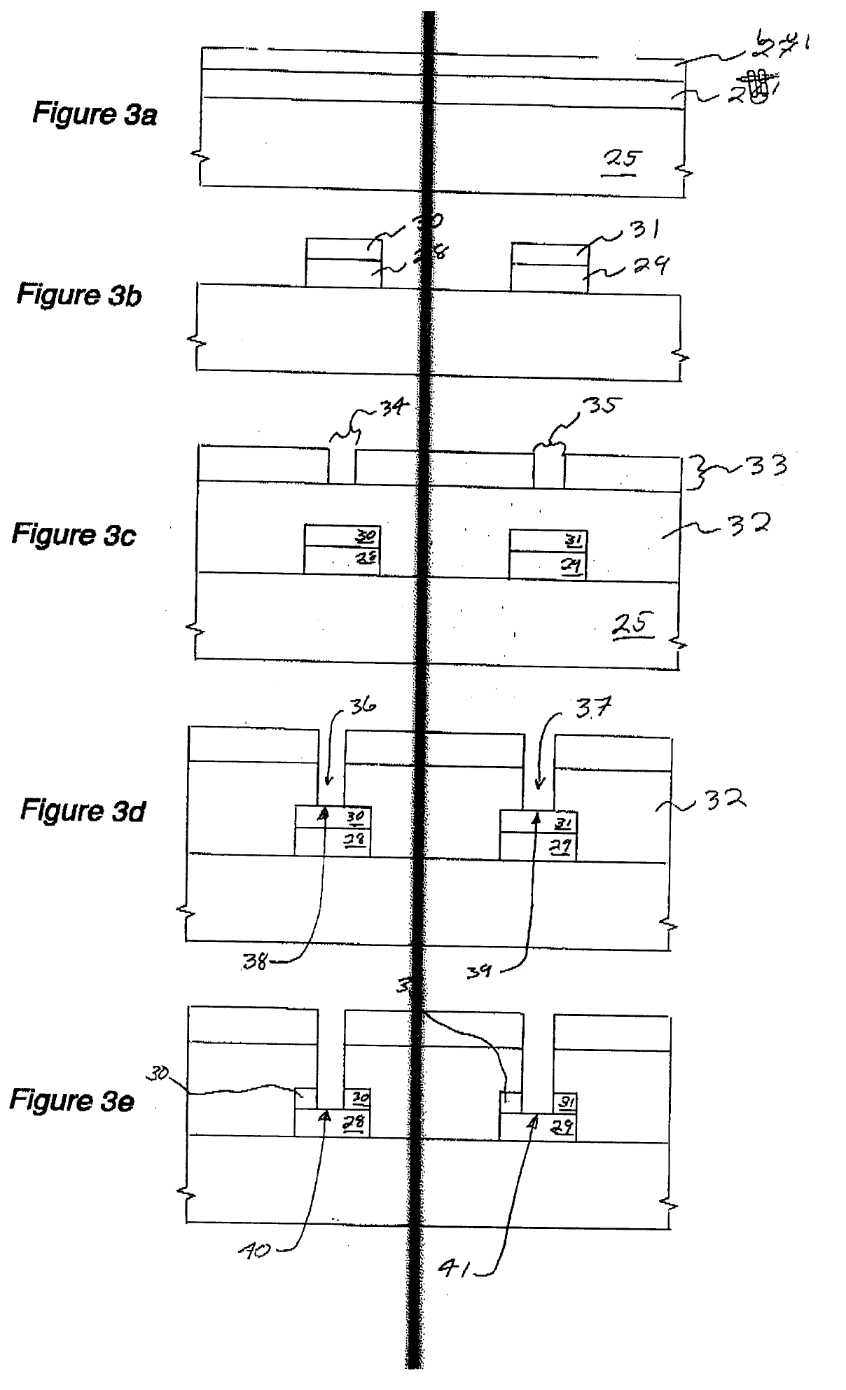

FIG. 3a shows a schematic crosssectional view of a portion of an in-process semidonductor integrated circuit chip wherein the integrated circuit components have been created within a semiconductor substrate 25. A first metal layer 26 of aluminum has been blanket deposited atop the exposed surface of the chip. A thin silicon nitride layer 27 (approximately 100 to 200 angstroms thick) has been blanket deposited atop the first metal layer.

In FIG. 3b, a photo-patterning etch step, has created first metal pads 28, 29 having silicon nitride cap regions 30, 31 atop their upper facing surfaces. The first metal pads contact certain device element or other conductive structures on or within the substrate of the IC chip.

In FIG. 3c, a layer of silicon dioxide 32 has been blanket deposited atop the expo ed upper surfaces of the in-process chip covering the nitride cap regions 30, 31 and exposed portions of the substrate 25. A photo-resist mask 33 has been formed atop the ox de layer and patterned with apertures 34, 35 corresponding to the locations where contact vias will be created.

The results of the remaining steps shown in FIGS. 3d and 3e are essentially the same as those steps described above with respect to FIGS. 2d and 2e of the first embodiment. A first anisotropic oxide etch which selectively stops on nitride is performed to form contact vias 36, 37 through the oxide layer 32 to the upward facing surfaces 38, 39 of each of the nitride cap regions 30, 31 existing above the first metal pads 28, 29. A second isotropic low-powered dry nitride etch is then performed to extend the vias through the nitride cap regions 30, 31 to the upward facing surfaces 40, 41 of the metal pads 28, 29 respectively.

The non-existence of the non-conductive aluminum compound contaminants on the via sidewalls increases the area of contact between the second metal fill and the aluminum first metal pad. This increases the overall conductivity of the contact, thereby allowing greater miniaturization. By eliminating other steps required to clean the vias prior to the deposition of the second metal fill, fabrication costs are reduced.

While the preferred embodiments of the invention have been described, modifications can be made and other embodiments may be devised without departing from the spirit of the invention and the scope of the appended claims.

What is claimed is:

1. In a double metal process for forming an electrically conductive contact to a conductive structure in a semiconductor integrated circuit, an improvement which comprises:
forming a first metal pad;
forming a silicon nitride (nitride) region atop said pad;
depositing a silicon dioxide (oxide) layer atop said nitride region;
generating a via through said oxide layer to said nitride region, said via terminating at an end situated above an interface between said nitride region and said first metal pad;
extending said via beyond said end through said nitride region to said first metal pad; and
depositing a second metal region into said via contacting said first metal pad.

2. The method of claim 1, wherein aid step of generating comprises:
patterning a photo-resist mask atop said oxide layer,
said step of patterning comprises forming an aperture in said mask, said aperture situated a distance above said first metal pad.

3. The method of claim 2, wherein said step of generating further comprises:
performing an anisotropic oxide etch which selectively stops on nitride, thereby removing portions of said oxide layer situated below said aperture and above said first metal pad.

4. The method of claim 3, wherein said step of extending comprises:
performing a low-powered isotropic nitride etch.

5. The method of claim 1, wherein said first metal pad is made from aluminum.

6. The method of claim 5, wherein said steps of forming a first metal pad and forming a silicon nitride (nitride) region atop said pad comprise:
depositing a first metal layer;
depositing a nitride layer atop said first metal layer; and
etching said nitride and first metal layers to form said first metal pad having a nitride cap, said cap forming said nitride region.

7. The method of claim 5, wherein said steps of forming a first metal pad and forming a silicon nitride (nitride) region atop said pad comprise:
depositing a first metal layer;
etching said first metal layer to form said first metal pad; and
depositing a nitride layer atop said first metal pad.

8. The method of claim 5, wherein said second metal region is made from a metal selected from the group consisting of tungsten, tungsten alloys, titanium, titanium alloys, aluminum, and aluminum alloys.

9. The method of claim 3, wherein said step of performing an anisotropic oxide etch occurs without penetrating through said nitride region to said first metal pad.

10. The method of claim 3, wherein said step of generating further comprises:
performing a low selective standard etch through said oxide layer to a distance above said nitride region, prior to said step of performing an anisotropic oxide etch.

11. The method of claim 4, wherein said low-powered isotropic nitride etch is a dry low-powered isotropic nitride etch.

12. The method of claim 1, wherein said nitride region is a thin layer between 100 and 200 angstroms thick.
